(19) United States
(12) Patent Application Publication
(10) Pub. No.: US 2025/0353759 A1
(43) Pub. Date: Nov. 20, 2025

(54) HIGH ENTROPY OXIDE, METHOD OF MAKING THE SAME, AND PHOTODETECTOR COMPRISING THE SAME

(71) Applicant: National Cheng Kung University, Tainan City (TW)

(72) Inventors: Jyh-Ming TING, Tainan City (TW); Chia-Yun CHEN, Tainan City (TW); Jyun-Yi LI, Tainan City (TW); Kuan-Yi KUO, Tainan City (TW)

(73) Assignee: National Cheng Kung University, Tainan City (TW)

(21) Appl. No.: 18/744,068

(22) Filed: Jun. 14, 2024

(30) Foreign Application Priority Data
May 16, 2024 (TW) 113118210

(51) Int. Cl. C01G 53/00; H01L 31/032; H01L 31/0392; H01L 31/18

(52) U.S. Cl. CPC C01G 53/82; H10F 71/00; H10F 77/12; H10F 77/169; C01P 2002/32; C01P 2002/72; C01P 2004/03; C01P 2006/60

(57) ABSTRACT

The present disclosure relates a high entropy oxide and preparation method thereof. Specifically, the present disclosure provides a high entropy oxide of formula (FeNiCrMnMgCu)O including spinel structure, and the spinel structure includes oxygen vacancy (O_{V}) concentration of 20 to 40%. The present disclosure further provides a photodetector, which includes a substrate, an absorbing layer comprising the high entropy oxide, and an electrode unit. With the plenty of oxygen vacancies, the high entropy oxide shows the excellent optical absorption properties, thereby having a bright prospect of the application.

### BACKGROUND

### 1. Technical Field

The present disclosure relates to a high entropy oxide, especially to a high entropy oxide used in a photodetector.

### 2. Description of Associated Art

A high entropy oxide (HEO) is an oxide consisting of at least five metal elements each at a concentration of about 5-35%, respectively, and has a configurational entropy (ΔS) larger than or equal to 1.5 R. Recently, high entropy oxides have become novel materials of interest, for example, as electrode active materials used in batteries in the field of energy, due to their excellent physical and chemical properties. However, there are few studies on the optical properties of high entropy oxides, thus the application of high entropy oxides in optical field is limited.

Further, in the conventional techniques in the optical field, a photodetector is commonly used to detect ultraviolet light with a wavelength of 10-400 nm, visible light with a wavelength of 400-760 nm, infrared light with a wavelength of 760 nm to 1 mm for, or terahertz radiation with a frequency of about 0.1-10 THz, etc. For example, a detector containing a Complementary Metal-Oxide-Semiconductor (CMOS) for visible light or a detector containing InGaAs or HgCdTe for infrared light. However, conventional photodetectors have at least one problem of the following: a low external quantum efficiency; a narrow range of optical absorption unable to cover incident light in the band ranging from ultraviolet, visible and infrared; the requirement to use at least two materials to absorb incident light in different bands to achieve a wide band spectral responsivity; a complicated manufacturing process commonly caused by adding desired elements through doping; high cost, making them only suitable as products with small size and high price.

Given the above, there is an urgent need for developing a high entropy oxide having excellent optical properties including spectral responsivity, detection rate, and response time, which can be applied to photodetectors and yield technical effects including a simple manufacturing process and the ability to respond to incident light over a wider range of wavelengths.

### SUMMARY

In order to solve the problems of conventional techniques mentioned above, the present disclosure provides a high entropy oxide represented by Formula (I) below:

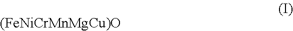

wherein the high entropy oxide may comprise a spinel structure, and the spinel structure comprises an oxygen vacancy concentration of 20-40%.

In an embodiment of the present disclosure, the spinel structure is a single phase spinel structure.

In another embodiment of the present disclosure, the spinel structure may have an oxygen vacancy concentration of 20-40%, preferably 25-35%.

In an embodiment of the present disclosure, the high entropy oxide may have an optical absorption property for at least one of ultraviolet light, visible light, and infrared light, preferably an optical absorption property for all of ultraviolet light, visible light and infrared light.

In an embodiment of the present disclosure, the high entropy oxide may have an optical absorption rage between 310 nm and 1400 nm.

The present disclosure further provides a preparation method of the high entropy oxide aforementioned, comprising: performing a hydrothermal reaction on a reaction solution containing metal salts, a surfactant, an oxidant and a solvent, wherein the metal salt comprises an iron salt, a nickel salt, a chromium salt, a manganese salt, a magnesium salt and a copper salt; isolating a precipitate from the reaction solution after the hydrothermal reaction; and performing a thermal treatment on the precipitate, yielding the high entropy oxide.

In an embodiment of the present disclosure, the metal salt may be one selected from the group consisting of a metal nitrate, a metal halide, a metal acetate and a metal sulfate, the surfactant may be one selected from the group consisting of (1-hexadecyl) trimethylammonium bromide, ammonium fluoride and citric acid, and the oxidant may be one selected from the group consisting of urea, sodium hydroxide, potassium hydroxide and ammonia water.

In an embodiment of the present disclosure, the hydrothermal reaction is performed at 120-180° C. for 2-8 hours.

In an embodiment of the present disclosure, the molar ratio of the oxidant to the total metal salts is from 2:1 to 8:1.

In an embodiment of the present disclosure, the thermal treatment is treating the precipitate at 700-1100° C. for 1-5 hours.

The present disclosure also provides a photodetector, comprising in sequence: a substrate; an absorption layer containing the high entropy oxide aforementioned, which is formed on and contact the substrate; and an electrode unit formed on the absorption layer to sandwich the absorption layer between the substrate and the electrode unit.

In an embodiment of the photodetector of the present disclosure, a back electrode formed on the substrate is further included to sandwich the substrate and the absorption layer between the electrode unit and the back electrode.

In an embodiment of the present disclosure, under light irradiation with a wavelength of 850 nm, the absorption layer has a photocurrent density of 1.0-1.5 mA/cm², preferably of 1.0-1.2 mA/cm², and more preferably of 1.1-1.2 mA/cm²; a spectral responsivity of 3.0-4.0 A/W, preferably of 3.5 A/W; and an external quantum efficiency greater than 700%, e.g., greater than 710%, 720%, 730%, 740%, or 750%.

All of the metal elements employed in the high entropy oxide of the present disclosure have similar ionic radii, valences and crystal structures, and are metal elements having high abundance in nature and low cost. In addition, the presence of Mg can stabilize the spinel structure and reduce the contact resistance; Cu cations preferentially distribute in the tetrahedral sites rather than octahedral sites in the spinel structure, so that the cations in the spinel structure are in low valence; and each of Fe, Ni, Mn, and Cr occupies two Wyckoff sites, forming various valences and forming oxygen vacancies.

The high entropy oxide of the present disclosure can have the property of spectral responsivity for incident light of ultraviolet, visible, and infrared bands due to its large oxygen vacancy concentration in the spinel structure and its unprecedented wide range of optical absorption.

In an aspect, the high entropy oxide of the present disclosure can be applied to photodetectors and have excellent stability and reliability due to its superior light absorbance and external quantum efficiency.

In another aspect, the photodetector containing the high entropy oxide of the present disclosure has improved spectral responsivity, detection rate and response time, as compared to a photodetector based on Si.

In yet another aspect, as compared to a binary material, a ternary material, a material to which elements are added by doping, or a composite material made by overlaying at least two materials, etc., the high entropy oxide of the present disclosure is used in the absorption layer of a photodetector as a single material without in combination with other materials and can achieve photoresponse to the incident light over a wide range of wavelengths. Also, the preparation method of the present disclosure is simple and can satisfy the high entropy standard, achieving the goal of reducing the complexity of the manufacturing process and reducing manufacturing cost, thereby being suitable for more photodetector products.

### BRIEF DESCRIPTION OF THE DRAWINGS

The embodiments of the present disclosure will be described through exemplary drawings:

FIG. 1A is the surface morphology of the high entropy oxide of the example of the present disclosure detected with a scanning electron microscopy.

FIG. 1B is the X-ray diffraction pattern of the high entropy oxides of the examples of the present disclosure.

FIG. 2 is the X-ray photoelectron spectroscopy spectra of the high entropy oxides of the examples of the present disclosure.

FIG. 3 is the absorbance plot of the high entropy oxides of the examples of the present disclosure.

FIG. 4 is a diagram showing the spatial structure of the photodetector of the example of the present disclosure.

FIG. 5 is a graph showing variation of external quantum efficiency with wavelength of the photodetector of the example of the present disclosure.

FIG. 6 is a graph showing variation of photocurrent density with time of the photodetector of the example of the present disclosure.

FIG. 7A is a graph showing variation of spectral responsivity with load of the photodetectors of the examples of the present disclosure.

FIG. 7B is a graph showing variation of spectral responsivity with temperature of the photodetectors of the examples of the present disclosure.

FIG. 7C is a graph showing variation of spectral responsivity with pH condition of the photodetectors of the examples of the present disclosure.

FIG. 8 is a graph showing the result of an on/off cycle measurement on the photodetector of the example of the present disclosure.

### DETAILED DESCRIPTION OF THE PREFERRED EMBODIMENTS

The execution modes of the present disclosure will be illustrated by following specific embodiments and/or referencing the figures, one having ordinary skill in the art can easily realize the advantages and effects of the present disclosure based on the content described in the description.

It should be noted that the structure, proportion, size, etc. shown in the figures in the specification are only used to match the contents disclosed in the specification for the understanding and reading of those having ordinary skill in the art, and are not intended to define the limiting conditions for the implementation of the present disclosure, so they have no technical significance. Any modification of the structure, change of the proportion relationship, or adjustment of the size, without affecting the efficacy and purpose of the present disclosure, should fall in the scope of the technical content disclosed in the present disclosure. Meanwhile, “lower”, “upper”, “a” and “an” recited in the specification are also used for clear description but not for defining the scope capable of being implemented by the present disclosure, the change or adjustment of their relative relationship without substantial alteration of the technical contents are also considered within the implementation scope of the present disclosure. Furthermore, all ranges and values recited in the present invention are inclusive and combinable. Any value or point falling in the ranges recited herein, such as any integers and decimals, can be used as the lower or upper limit to derive a subrange.

The present disclosure provides a high entropy oxide represented by Formula (I) below:

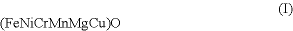

wherein the high entropy oxide may comprise a spinel structure, and the spinel structure comprises an oxygen vacancy concentration of 20-40%.

In an embodiment of the present disclosure, the spinel structure is a single phase spinel structure.

In another embodiment of the present disclosure, the spinel structure may have an oxygen vacancy concentration of 20-40%, preferably of 25-35%, e.g., an oxygen vacancy concentration of 20%, 21%, 22%, 23%, 24%, 25%, 26%, 27%, 28%, 29%, 30%, 31%, 32%, 33%, 34%, 35%, 36%, 37%, 38%, 39%, or 40%.

In an embodiment of the present disclosure, the high entropy oxide may have an optical absorption property for at least one of ultraviolet light, visible light, and infrared light, preferably an optical absorption property for all of ultraviolet light, visible light and infrared light.

In an embodiment of the present disclosure, the high entropy oxide may have an optical absorption range between 310 nm and 1400 nm, e.g., an optical absorption range between any two of 310, 350, 400, 450, 500, 550, 600, 650, 700, 750, 800, 850, 900, 950, 1000, 1100, 1200, 1300, and 1400 nm.

To obtain the high entropy oxide of the present disclosure, the present disclosure further provides a preparation method of the high entropy oxide aforementioned, comprising: performing a hydrothermal reaction on a reaction solution containing metal salts, a surfactant, an oxidant and a solvent, wherein the metal salt comprises an iron salt, a nickel salt, a chromium salt, a manganese salt, a magnesium salt and a copper salt; isolating a precipitate from the reaction solution after the hydrothermal reaction; and performing a thermal treatment on the precipitate, yielding the high entropy oxide.

In an embodiment of the present disclosure, the metal salt may be one selected from the group consisting of a metal nitrate, a metal halide, a metal acetate and a metal sulfate. More specifically, the iron salt, the nickel salt, the chromium salt, the manganese salt, the magnesium salt, and the copper salt may be independently selected from nitrates, halides, acetates, and/or sulfates. The surfactant may be one selected from the group consisting of (1-hexadecyl) trimethylammonium bromide, ammonium fluoride and citric acid, and the oxidant may be one selected from the group consisting of urea, sodium hydroxide, potassium hydroxide and ammonia water.

In an embodiment of the present disclosure, the hydrothermal reaction is performed at 120-180° C. for 2-8 hours.

In an embodiment of the present disclosure, the molar ratio of the oxidant to the total metal salts is from 2:1 to 8:1.

In an embodiment of the present disclosure, the thermal treatment is treating the precipitate at 700-1100° C. for 1-5 hours. In other embodiments, the thermal treatment temperature comprises, but not limited to, 700, 750, 800, 850, 900, 950, 1000, 1050, or 1100° C.; and the treatment time comprises, but not limited to, 1, 1.5, 2, 2.5, 3, 3.5, 4, 4.5, or 5 hours. Specifically, the temperature may be ramped by a rate of 5° C./min to 700-1100° C. at which the precipitate may be annealed for 1-5 hours.

The present disclosure will be described in detail through Examples which are not considered to limit the scope of the present disclosure.

### EXAMPLES

### Preparation of Metal Oxides Containing Multiple Metal

### Example 1: (FeNiCrMnMgCu)O

A solvent, metal salts, a surfactant and an oxidant were provided. Specifically, the solvent was deionized water; the metal salts contained Fe(NO₃)₃·9H₂O, Ni(NO₃)₂·6H₂O, Cr(NO₃)₃·9H₂O, Mn(NO₃)₂·6H₂O, Mg(NO₃)₂6H₂O and Cu(NO₃)₂·2.5H₂O; the surfactant was (1-hexadecyl)trimethylammonium bromide (CTAB); and the oxidant was urea.

Firstly, equimolar (1 mmol) of each metal salts were dissolved in 40 ml of solvent, 1.25 mmol of the surfactant was added with stirring, then 36 mmol of the oxidant was added in the proviso that the molar ratio of the oxidant to the total metal salts was 6:1, forming a reaction solution in a uniform phase.

Next, the reaction solution was placed in a stainless steel autoclave with a polytetrafluoroethylene lining and subjected to a hydrothermal reaction at 140° C. for 5hours. After the hydrothermal reaction was completed, the reaction mixture was cooled to room temperature to obtain a slurry.

The slurry was washed with deionized water and ethanol as the washing agents and then centrifuged to give a precipitate. Thereafter, the precipitate was dried in a vacuum oven at 60° C. for 12 hours, and the resulting powder was collected. Finally, the powder was heated at a ramp rate of 5° C./min to 900° C. and annealed for 2 hours to yield the sample of Example 1.

### Comparative Example 1: (FeNiCrMnMg)O

The sample of Comparative Example 1 was prepared in the same manner as in Example 1.

Comparative Example 1 differed from Example 1 in that, in Comparative Example 1, the metal salts comprised Fe(NO₃)₃·9H₂O, Ni(NO₃)₂·6H₂O, Cr(NO₃)₃·9H₂O, Mn(NO₃)₂·6H₂O and Mg(NO₃)₂·6H₂O; and 25 mmol of the oxidant was added in proviso that the molar ratio of the oxidant to the total metal salts was 5:1

### Comparative Example 2: (FeNiCrMn)O

The sample of Comparative Example 1 was prepared in the same manner as in Example 1.

Comparative Example 2 differed from Example 1 in that, in Comparative Example 2, the metal salts comprised Fe(NO₃)₃·9H₂O, Ni(NO₃)₂·6H₂O, Cr(NO₃)₃·9H₂O and Mn(NO₃)₂·6H₂O; and 16 mmol of the oxidant was added in proviso that the molar ratio of the oxidant to the total metal salts was 4:1.

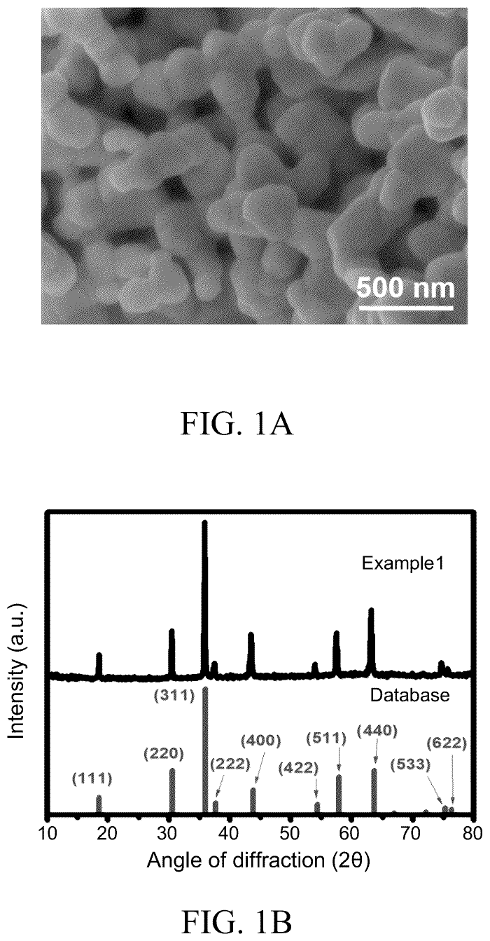

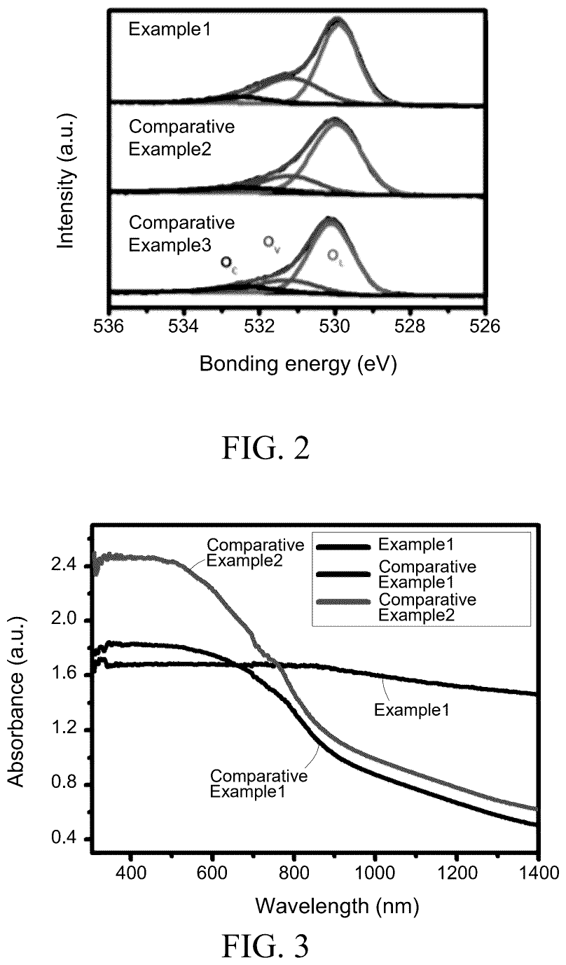

The samples prepared above were subjected to the following analyses:
(1) Surface observation: the sample of Example 1 was observed under a scanning electron microscopy (SEM, JEOL 6701F) for the morphology and size, and the result was recorded in FIG. 1A, demonstrating that the sample of the present disclosure had a nanostructure.
(2) Crystalline property: the sample of Example 1 was analyzed on by X-ray diffraction analyzer (XRD, Bruker D8 Discover) for the crystalline structure, and the result was compared to a standard database (JCPDS No. 23-1237) and recorded in FIG. 1B, demonstrating that the sample of the present disclosure had a single phase spinel structure.
(3) Analysis of element concentrations: the samples of Example 1 and Comparative Examples 1 to 3 were analyzed by an inductively coupled plasma-mass spectrometer (ICP-MS, Thermo-Element XR) for the concentration of each metal element and were calculated for their configurational entropy ΔS, and the results were recorded in Table 1, demonstrating that the sample of Example 1 of the present disclosure was a high entropy oxide.
(4) Surface oxidation state assay: the samples of Example 1 and Comparative Examples 1 to 3 were detected by a high resolution X-ray photoelectron spectrometer (XPS, Versaprobe PHI 5000) for lattice oxygen (O_{L}), oxygen vacancies (O_{V}) and surface-adsorbed oxygen (O_{C}), and the results were recorded in FIG. 2, demonstrating there were oxygen vacancies in the samples. The concentration of the oxygen vacancies was analyzed and recorded in Table 1.
(5) Assay of optical absorption property: the high entropy oxide of Example 1 of the present application was detected by a UV-VIS-NIR spectrometer (Hitachi U-4100) for the absorbance under different incident light of ultraviolet (UV), visible (VIS) and near-infrared (NIR) bands, and the results were recorded in FIG. 3.

TABLE 1

| | Fe | Ni | Mn | Cr | Mg | Cu | | Ov |
|---|---|---|---|---|---|---|---|---|
| | (%) | (%) | (%) | (%) | (%) | (%) | ΔS | (%) |
| Example 1 | 17.9 | 18.1 | 16.1 | 20.6 | 18.3 | 9.0 | 1.76R | 30.2 |
| Comparative | 21.6 | 19.9 | 18.2 | 20.6 | 19.7 | — | 1.61R | 19.4 |
| Example 1 | | | | | | | | |
| Comparative | 15.2 | 21.0 | 37.9 | 25.9 | — | — | 1.33R | 17.2 |
| Example 2 | | | | | | | | |

From the results in Table 1 and FIG. 3, it can be seen that the high entropy oxide of the present disclosure, by the high oxygen vacancies concentration, promoted the effective cycles that holes were generated by light excitation but did not combine with electrons to form electron-hole pairs, thereby achieving a desired absorbance of about 1.4-1.8 a.u. and unexpected ultra-wide absorption range from about 310 nm to 1400 nm.

### Photodetector

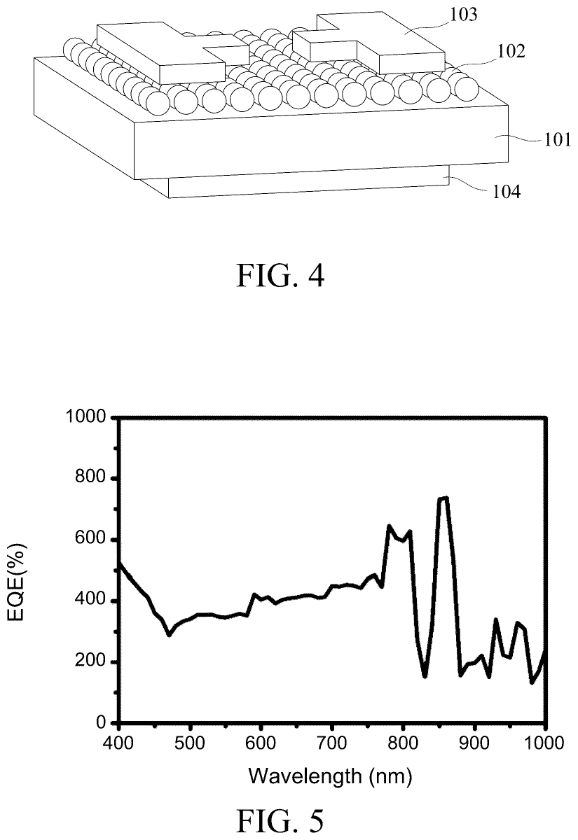

As shown in FIG. 4, the present disclosure also provided a photodetector 100, which comprises in sequence: a substrate 101; an absorption layer 102 containing the high entropy oxide of the present disclosure, which was formed on and contacted the substrate 101; an electrode unit 103 formed on the absorption layer 102 to sandwich the absorption layer 102 between the substrate 101 and the electrode unit 103; and optionally, a back electrode 104 formed on the substrate 101 to sandwich the substrate 101 and the absorption layer 102 between the electrode unit 103 and the back electrode 104.

In an embodiment of the present disclosure, under light irradiation with a wavelength of 850 nm, the absorption layer has a photocurrent density of 1.0-1.5 mA/cm², preferably of 1.0-1.2 mA/cm², more preferably of 1.1-1.2 mA/cm²; a spectral responsivity of 3.0-4.0 A/W, preferably of 3.5 A/W; and an external quantum efficiency greater than 700%, e.g., greater than 710%, 720%, 730%, 740%, or 750%.

### Example 2: Photodetector of the Present Disclosure

In the photodetector of Example 2, the material of the electrode unit was Ag, the material of the absorption layer was (FeNiCrMnMgCu)O, and the material of the substrate was Si.

The high entropy oxide powder prepared in Example 1 was dispersed in ethanol at a concentration of 0.2 mg/ml, and the ethanol dispersion in which the high entropy oxide is dispersed was coated onto a Si substrate using spin coating at 2000 rpm. Then, the Si substrate coated with the high entropy oxide powder was dried at 70° C. for 30 minutes. A T-shaped front silver electrode (130 nm thick) was vaporized and deposited on the layer of the high entropy oxide powder using an electron gun. In addition, a 130 mm thick back Al electrode was deposited in the same manner.

### Comparative Example 3: Traditional Photodetector

In the traditional photodetector of Comparative Example 3, the material of an electrode unit was Ag, the material of an absorption layer was PEDOT:PSS (poly(3,4-ethylenedioxythiophene):poly(styrenesulfonate)), and the material of a substrate was Si.

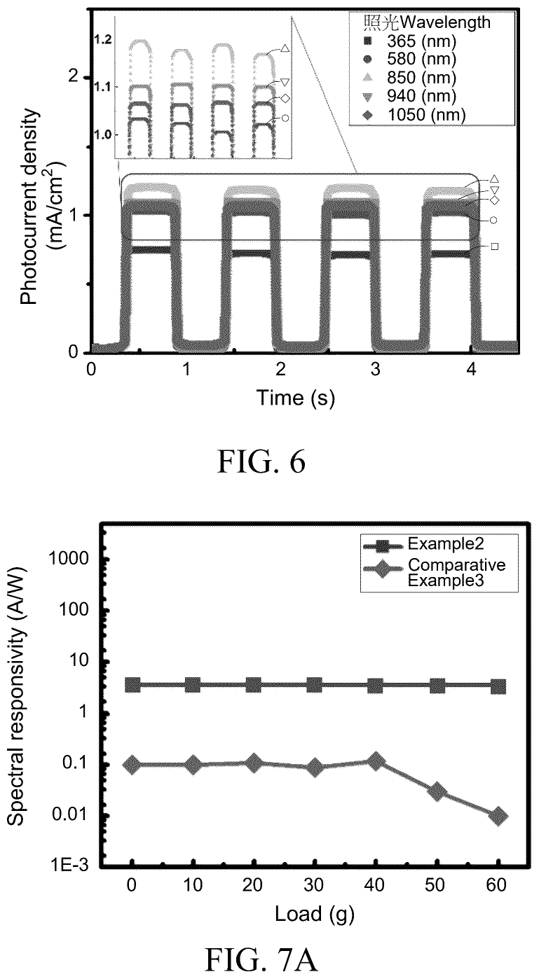

Firstly, the photodetector of Example 2 was subjected to the following analyses:
(6) Assay of photoelectric conversion efficiency: by an incident photon-electron conversion efficiency (IPCE, Model 69911, Newport) measurement, the high entropy oxide (FeNiCrMnMgCu)O used as the absorption layer in the photodetector of Example 2 of the present application was tested for the external quantum efficiency (EQE) at different incident wavelengths, and the result was recorded in FIG. 5, demonstrating that the high entropy oxide of the present disclosure yielded an external quantum efficiency of about 732% at an incident wavelength of 850 nm.
(7) Assay of photodetective function: by an incident photon-electron conversion efficiency (IPCE, Model 69911, Newport) measurement, the photodetector of Example 2 of the present application was test for the optical on-off switch photoresponse when operating at incident wavelengths of 365, 580, 850, 940 and 1050 nm and a bias voltage of 1 V, and the results were recorded in FIG. 6, demonstrating that the high entropy oxide of the present disclosure had a wide photoresponse range from 365 nm to 1050 nm and a wide-spectrum photocurrent density of about 1.2 mA/cm², i.e., had an excellent wide-band photodetective function.
(8) Assays of the spectral responsivity, detection rate and current on/off ratio: the spectral responsivities, the detection rates and the current on/off ratios of the photodetector of Example 2 of the present application at different incident wavelengths were as shown in Table 2.

TABLE 2

| Incident | Spectral | Detection | |
|---|---|---|---|
| wavelength | Responsivity | rate D | Current on/off |
| λ (nm) | R (A/W) | (Jones) | ratio Iₒₙ/I_{off} |
| 365 | 2.3 | 3.0*10¹³ | 44,522 |
| 580 | 2.8 | 3.7*10¹³ | 54,201 |
| 850 | 3.5 | 4.6*10¹³ | 67,751 |
| 940 | 3.1 | 4.1*10¹³ | 60,008 |
| 1000 | 2.9 | 3.8*10¹³ | 56,136 |

As can be seen from Table 2, the high entropy oxide of the present disclosure had an excellent spectral responsivity, a high detection rate and an improved current on/off ratio at an incident wavelength of 850 nm.

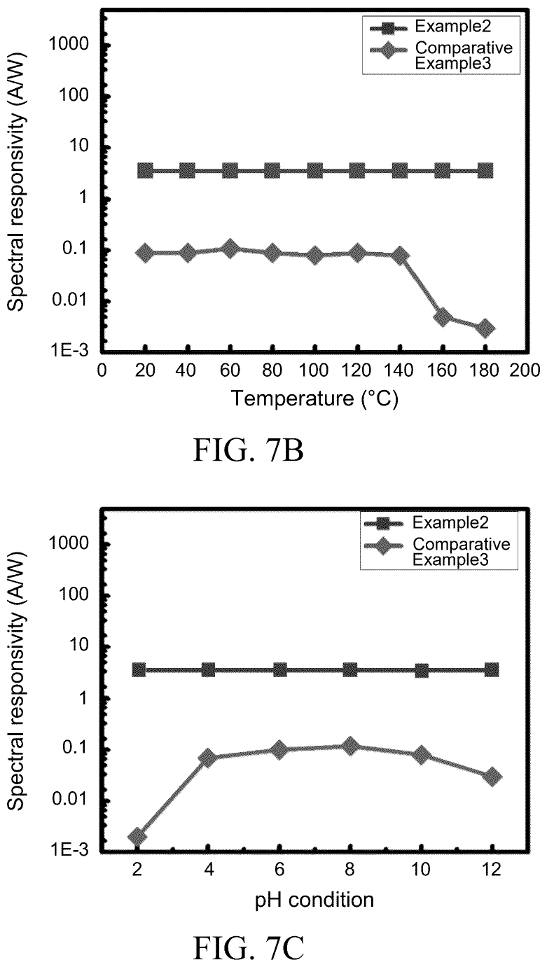

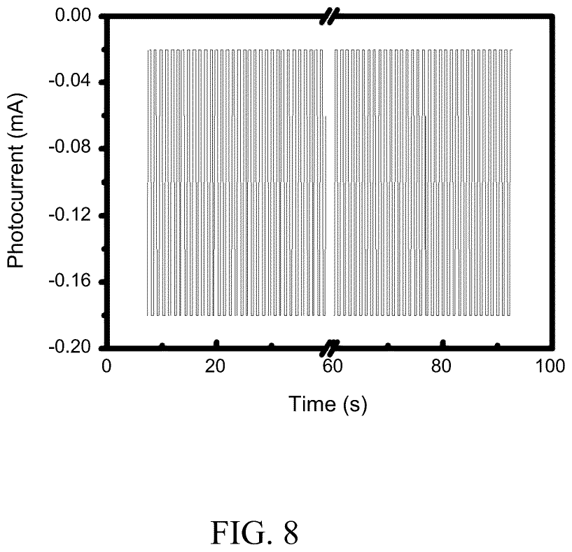

In addition, the photodetectors of Example 2 and Comparative Example 3 were subjected to the following analyses:
(9) Abrasion test: the photodetectors of Example 2 and Comparative Example 3 were abraded with different loads ranging from 0 to 60 g and tested for their spectral responsivities, and the results were as shown in FIG. 7A. After calculation, with a load of 60 g, the photodetector of Example 2 had a spectral responsivity reduced by about 5.6%, and the photodetector of Comparative Example 3 had a spectral responsivity reduced by about 91.7%.
(10) High temperature resistance test: the photodetectors of Example 2 and Comparative Example 3 were heated at different temperatures ranging from 20° C. to 180° C. for 1 hour and tested for their spectral responsivities, and the results were as shown in FIG. 7B. After calculation, with a temperature of 180° C., the photodetector of Example 2 had a spectral responsivity reduced by about 0.56%, and the photodetector of Comparative Example 3 had a spectral responsivity reduced by about 97.3%.
(11) Acid/base resistance test: the photodetectors of Example 2 and Comparative Example 3 were immersed at different pH ranging from pH 2 to 12 for 1 minute and tested for their spectral responsivities, and the results were as shown in FIG. 7C. After calculation, with a pH 2, the photodetector of Example 2 had a spectral responsivity with a negligible reduction (by about 0.57%), and the photodetector of Comparative Example 3 had a spectral responsivity with a significant reduction.

Finally, the photodetector of Example 2 with the best teased performance was subjected to the following analysis:
(12) On/off cycle assay: the photodetector of Example 2 was subjected to a long-term on/off transient signal analysis, and the result was shown in FIG. 8. Obviously, the spectral responsivity of the photodetector having the high entropy oxide of the present disclosure as the absorption layer did not reduce.

As can be seen from the results above, the photodetector containing the high entropy oxide of the present disclosure had excellent stability and reliability.

What is claimed is:

1. A high entropy oxide represented by Formula (I) below: 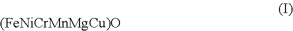
wherein the high entropy oxide comprises a spinel structure, and the spinel structure comprises an oxygen vacancy concentration of 20-40%.

2. The high entropy oxide of claim 1, wherein the spinel structure is a single phase spinel structure.

3. The high entropy oxide of claim 1, wherein the spinel structure comprises an oxygen vacancy concentration of 25-35%.

4. The high entropy oxide of claim 1, having an optical absorption property for at least one of ultraviolet light, visible light and near-infrared light.

5. The high entropy oxide of claim 1, having an optical absorption range between 310 nm and 1400 nm.

6. A preparation method of the high entropy oxide of claim 1, comprising:
performing a hydrothermal reaction on a reaction solution containing metal salts, a surfactant, an oxidant and a solvent, wherein the metal salt comprises an iron salt, a nickel salt, a chromium salt, a manganese salt, a magnesium salt and a copper salt;
isolating a precipitate from the reaction solution after the hydrothermal reaction; and
performing a thermal treatment on the precipitate, yielding the high entropy oxide.

7. The preparation method of claim 6, wherein the metal salt is one selected from the group consisting of a metal nitrate, a metal halide, a metal acetate and a metal sulfate, the surfactant is one selected from the group consisting of (1-hexadecyl) trimethylammonium bromide, ammonium fluoride and citric acid, and the oxidant is one selected from the group consisting of urea, sodium hydroxide, potassium hydroxide and ammonia water.

8. The preparation method of claim 6, wherein the hydrothermal reaction is performed at 120-180° C. for 2-8 hours.

9. The preparation method of claim 6, wherein the thermal treatment is treating the precipitate at 700-1100° C. for 1-5 hours.

10. The preparation method of claim 6, wherein the molar ratio of the oxidant to the total metal salts is from 2:1 to 8:1.

11. A photodetector, comprising in sequence:
a substrate;
an absorption layer comprising the high entropy oxide of claim 1, which is formed on and contacts the substrate; and
an electrode unit formed on the absorption layer to sandwich the absorption layer between the substrate and the electrode unit.

12. The photodetector of claim 11, wherein the absorption layer has a photocurrent density of 1.0-1.5 mA/cm², a spectral responsivity of 3.0-4.0 A/W and an external quantum efficiency greater than 700% under light irradiation with a wavelength of 850 nm.
